(19) United States
(12) Patent Application Publication
(10) Pub. No.: US 2025/0113428 A1
(43) Pub. Date: Apr. 3, 2025

(54) TECHNOLOGIES FOR AN ELECTROMAGNETIC INTERFERENCE SHIELD

(71) Applicant: Intel Corporation, Santa Clara, CA (US)

(72) Inventors: Min Suet Lim, Gelugor (MY); Eng Huat Goh, Ayer Itam (MY); Tin Poay Chuah, Bayan Lepas (MY); Kavitha Nagarajan, Bangalore (IN); Telesphor Kamgaing, Chandler, AZ (US); Poh Boon Khoo, Bayan Lepas (MY); Jiun Hann Sir, Gelugor (MY)

(21) Appl. No.: 18/478,967

(22) Filed: Sep. 29, 2023

(51) Int. Cl. H05K 1/02; H05K 1/11; H05K 1/18; H05K 3/34; H05K 3/40

(52) U.S. Cl. CPC H05K 1/0216; H05K 1/0277; H05K 1/111; H05K 1/181; H05K 1/182; H05K 3/341; H05K 3/4007; H05K 2201/0723

(57) ABSTRACT

Technologies for a shield for electromagnetic interference include a circuit board with an integrated circuit package on it, with a hole in the circuit board under the integrated circuit package. The integrated circuit package may include one or more dies or other components on the underside of the package, at least partially positioned in the hole in the circuit board. An electromagnetic shield box can be positioned in the hole. Tabs of the electromagnetic shield box may interface with pads on the same side of the circuit board as the integrated circuit package. The electromagnetic shield box may prevent or reduce electromagnetic or radiofrequency interference on the components of the integrated circuit package. Positioning the electromagnetic shield box can reduce the overall height of the circuit board, among other advantages.

### BACKGROUND

High-performance integrated circuit components and circuit boards with a low profile are important for small-form-factor devices such as cell phones, tablets, and laptops. Incorporating dies such as memory dies on a flip side of a package can improve the performance of certain integrated circuit components such as a processor. However, integrating dies on the flip side of a chip can increase the height of a package. Removing part of the circuit board that the package is mounted on can allow the package to have dies on the flip side without increasing the height of the package above the circuit board, but removing part of the circuit board raises issues such as less area to route signals and risk of electromagnetic/radiofrequency interference.

### BRIEF DESCRIPTION OF THE DRAWINGS

FIG. 1 is an isometric view of one embodiment of a system with an integrated circuit component on a circuit board with an electromagnetic shield box below the integrated circuit component.

FIG. 2 is a view of the system of FIG. 1 with the integrated circuit component and the electromagnetic shield box separated from the circuit board.

FIG. 3 is a cross-sectional view of the system of FIG. 1.

FIG. 4 is a cross-sectional view of the system of FIG. 1 with the integrated circuit component and the electromagnetic shield box separated from the circuit board.

FIG. 5 is an isometric view of an underside of the electromagnetic shield box of FIG. 2.

FIG. 6 is an isometric view of an underside of the integrated circuit component of FIG. 1.

FIG. 7 is a cross-sectional view of the system of FIG. 1 with one or more signals routed on the electromagnetic shield box.

FIG. 8 is a top-down view of the electromagnetic shield box of FIG. 7.

FIG. 9 is a cross-sectional view of the system of FIG. 1 with a low-profile electromagnetic shield box.

FIG. 10 is a flowchart of one embodiment of a method of creating the system of FIG. 1.

FIG. 11 is a cross-sectional view of one embodiment of a system at one stage of the flowchart of FIG. 10.

FIG. 12 is a bottom view of one embodiment of one stage of assembling an electromagnetic shield box.

FIG. 13 is a cross-sectional view of one embodiment of a system at one stage of the flowchart of FIG. 10.

FIG. 14 is a top view of a wafer and dies that may be included in a microelectronic assembly, in accordance with any of the embodiments disclosed herein.

FIG. 15 is a cross-sectional side view of an integrated circuit device that may be included in a microelectronic assembly, in accordance with any of the embodiments disclosed herein.

FIGS. 16A-16D are perspective views of example planar, gate-all-around, and stacked gate-all-around transistors.

FIG. 17 is a cross-sectional side view of an integrated circuit device assembly that may include a microelectronic assembly, in accordance with any of the embodiments disclosed herein.

FIG. 18 is a block diagram of an example electrical device that may include a microelectronic assembly, in accordance with any of the embodiments disclosed herein.

### DETAILED DESCRIPTION

In various embodiments disclosed herein, a circuit board has an integrated circuit package mounted on it. The integrated circuit package may have dies mounted on a bottom side, towards the circuit board. The circuit board has a hole below the integrated circuit package to accommodate the dies mounted on the bottom side. In order to prevent or reduce electromagnetic interference, an electromagnetic shield box is positioned in the hole of the motherboard. The electromagnetic shield box is mounted on the same side of the circuit board as the integrated circuit package, reducing the height of the system compared to mounting the electromagnetic shield on the other side of the circuit board. In some embodiments, the electromagnetic shield box may include signal traces, allowing for signals to be routed under the integrated circuit package and across the hole in the circuit board.

As used herein, the phrase “communicatively coupled” refers to the ability of a component to send a signal to or receive a signal from another component. The signal can be any type of signal, such as an input signal, an output signal, or a power signal. A component can send or receive a signal to another component to which it is communicatively coupled via a wired or wireless communication medium (e.g., conductive traces, conductive contacts, air). Examples of components that are communicatively coupled include integrated circuit dies located in the same package that communicate via an embedded bridge in a package substrate and an integrated circuit component attached to a printed circuit board that send signals to or receives signals from other integrated circuit components or electronic devices attached to the printed circuit board.

In the following description, specific details are set forth, but embodiments of the technologies described herein may be practiced without these specific details. Well-known circuits, structures, and techniques have not been shown in detail to avoid obscuring an understanding of this description. Phrases such as “an embodiment,” “various embodiments,” “some embodiments,” and the like may include features, structures, or characteristics, but not every embodiment necessarily includes the particular features, structures, or characteristics.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or any other manner. “Connected” may indicate elements are in direct physical or electrical contact, and “coupled” may indicate elements co-operate or interact, but they may or may not be in direct physical or electrical contact. Furthermore, the terms “comprising,” “including,” “having,” and the like, as used with respect to embodiments of the present disclosure, are synonymous. Terms modified by the word “substantially” include arrangements, orientations, spacings, or positions that vary slightly from the meaning of the unmodified term. For example, the central axis of a magnetic plug that is substantially coaxially aligned with a through hole may be misaligned from a central axis of the through hole by several degrees. In another example, a substrate assembly feature, such as a through width, that is described as having substantially a listed dimension can vary within a few percent of the listed dimension.

It will be understood that in the examples shown and described further below, the figures may not be drawn to scale and may not include all possible layers and/or circuit components. In addition, it will be understood that although certain figures illustrate transistor designs with source/drain regions, electrodes, etc. having orthogonal (e.g., perpendicular) boundaries, embodiments herein may implement such boundaries in a substantially orthogonal manner (e.g., within +/−5 or 10 degrees of orthogonality) due to fabrication methods used to create such devices or for other reasons.

Reference is now made to the drawings, which are not necessarily drawn to scale, wherein similar or same numbers may be used to designate the same or similar parts in different figures. The use of similar or same numbers in different figures does not mean all figures including similar or same numbers constitute a single or same embodiment. Like numerals having different letter suffixes may represent different instances of similar components. The drawings illustrate generally, by way of example, but not by way of limitation, various embodiments discussed in the present document.

In the following description, for purposes of explanation, numerous specific details are set forth in order to provide a thorough understanding thereof. It may be evident, however, that the novel embodiments can be practiced without these specific details. In other instances, well-known structures and devices are shown in block diagram form in order to facilitate a description thereof. The intention is to cover all modifications, equivalents, and alternatives within the scope of the claims.

As used herein, the phrase “located on” in the context of a first layer or component located on a second layer or component refers to the first layer or component being directly physically attached to the second part or component (no layers or components between the first and second layers or components) or physically attached to the second layer or component with one or more intervening layers or components.

As used herein, the term “adjacent” refers to layers or components that are in physical contact with each other. That is, there is no layer or component between the stated adjacent layers or components. For example, a layer X that is adjacent to a layer Y refers to a layer that is in physical contact with layer Y.

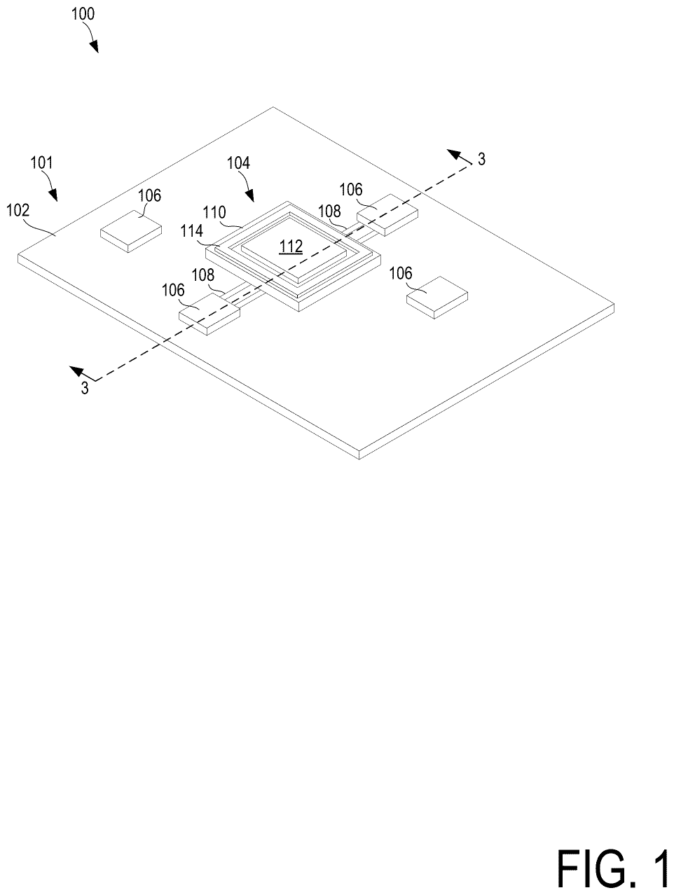

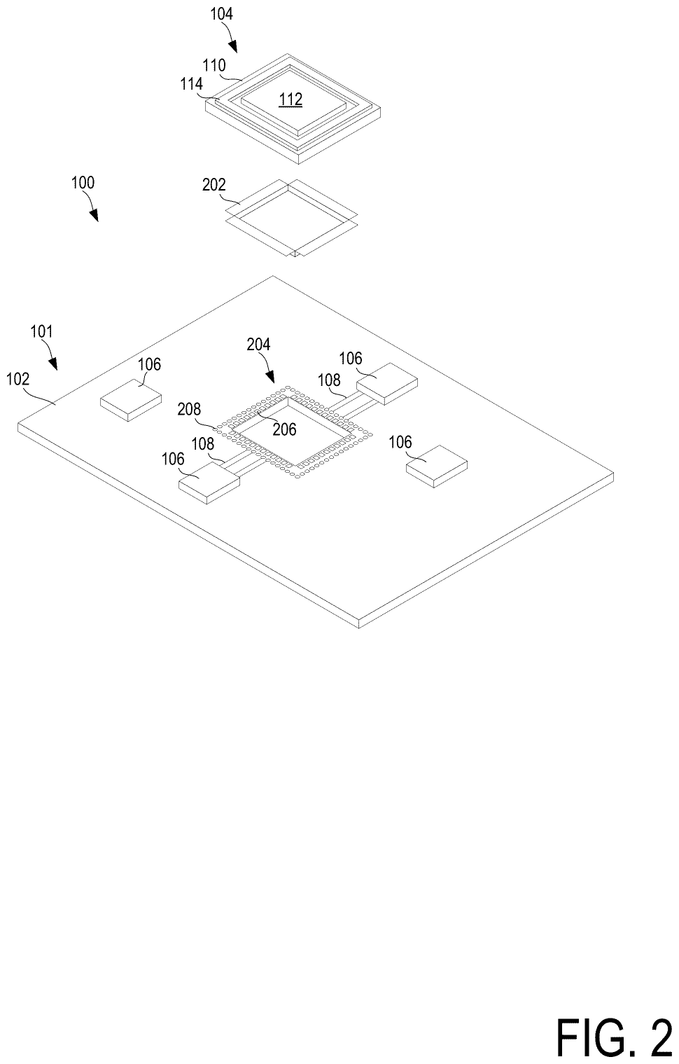

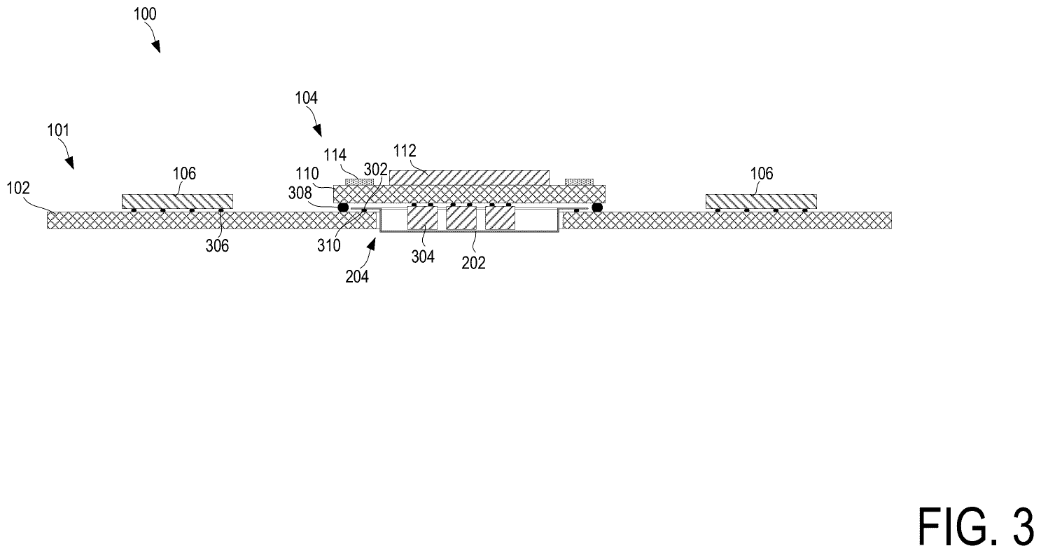

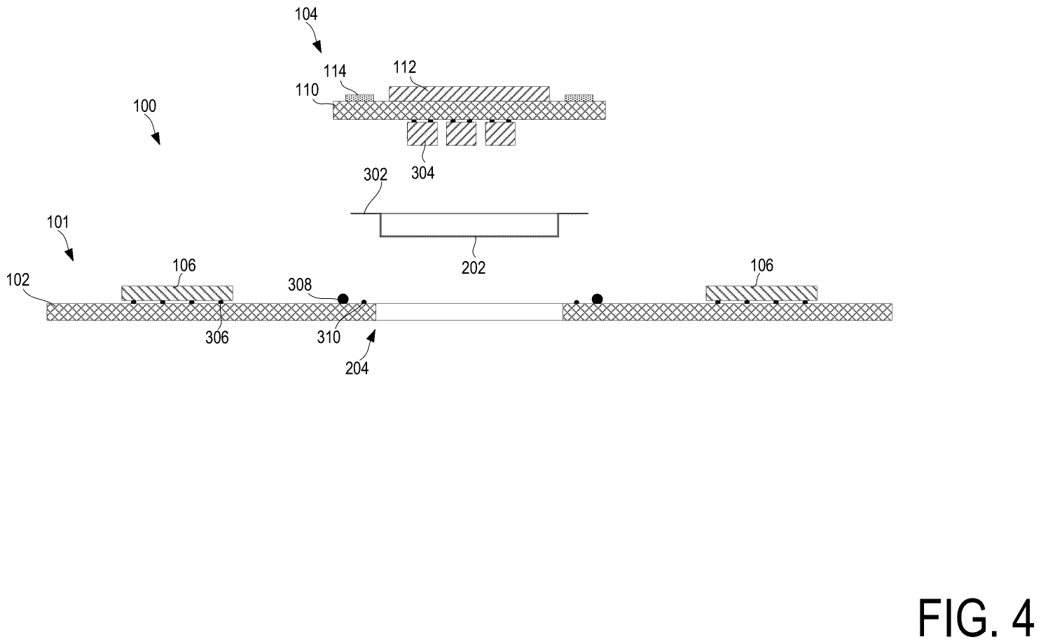

Referring now to FIG. 1-4, in one embodiment, a system 100 includes a circuit board 101 on which one or more integrated circuit packages 104 are mounted, with an electromagnetic shield box 202 below the integrated circuit package 104. FIG. 1 shows an isometric view of the system 100, FIG. 2 shows an isometric view of system 100 with the electromagnetic shield box 202 and the integrated circuit package 104 separated from a substrate 102 of the circuit board 101, FIG. 3 shows a cross-sectional view of the system 100, and FIG. 4 shows a cross-sectional view of the system 100 with the electromagnetic shield box 202 and the integrated circuit package 104 separated from the substrate 102 of the circuit board 101. Additional components 106, such as integrated circuit packages 106 or dies 106, may be mounted on the circuit board 101 as well and connected to the circuit board 101 by solder 306. The integrated circuit package 104 may include a circuit board 110, one or more dies 112 mounted on a top side of the circuit board 110, and one or more dies 304 mounted on a bottom side (or land side) of the circuit board 110. The integrated circuit package 104 may include a stiffener 114 for mechanical support. One or more traces 108 on the circuit board 101 may carry power, data signals, or other signals between different parts of the circuit board 101, such as to and/or from the components 106 and/or the integrated circuit package 104.

It should be appreciated that, as used herein, the “top side,” “bottom side,” etc., is an arbitrary designation used for clarity and does not denote a particular required orientation for manufacture or use. Although the illustrative embodiment described has the integrated circuit package 104, the electromagnetic shield box 202, etc., placed on the “top” side of the circuit board 101, in some embodiments, those components may be placed on the “bottom” side of the circuit board 101.

In an illustrative embodiment, the substrate 102 of the circuit board 101 has a hole 204 in it. The dies 304 mounted on the bottom side of the circuit board 110 of the integrated circuit package 104 can extend into the hole 204, allowing the integrated circuit package 104 to be mounted closer to the top side of the circuit board 101 without colliding with the substrate 102. The electromagnetic shield box 202 is disposed in the hole 204, shielding the dies 304 and other components from emitting or receiving electromagnetic or radiofrequency interference. The electromagnetic shield box 202 is mounted on the top side of the circuit board 101. The electromagnetic shield box 202 is mounted on one or more pads 206, and the integrated circuit package 104 is mounted on one or more pads 208. The pads 206 may be used to couple the electromagnetic shield box 202 to a ground signal or ground plane of the circuit board 101 or system 100.

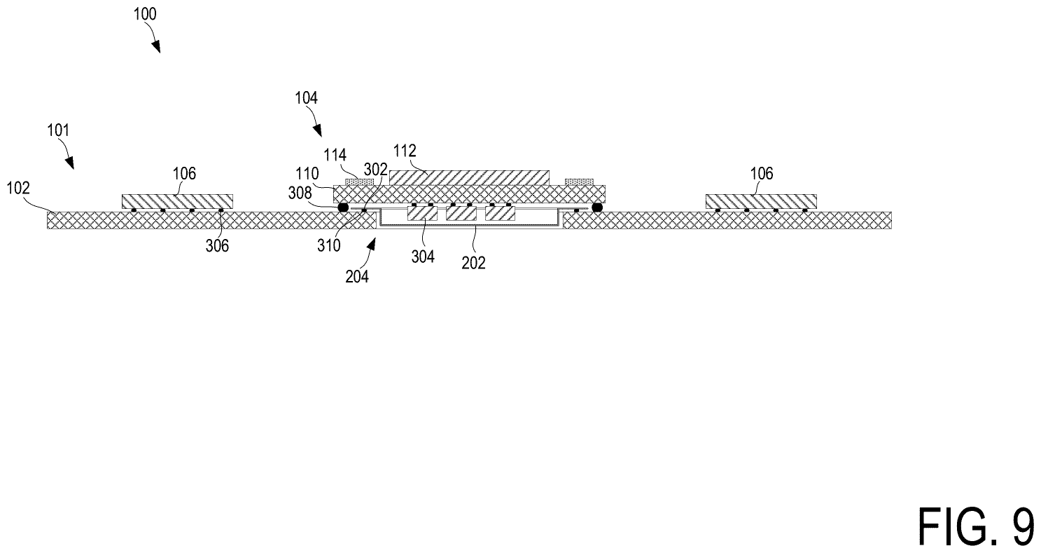

In an illustrative embodiment, the system 100 provides several advantages. The dies 304 mounted on the bottom side of the circuit board 110 of the integrated circuit package 104 can extend into the hole 204, reducing the overall height of the system. Unlike a hole drilled partway through the substrate 102, a hole that extends all the way through the substrate 102 is relatively inexpensive. Additionally, a hole partially through the substrate 102 can weaken the mechanical structure of the substrate 102, while a rigid electromagnetic shield box 202 can strengthen the circuit board 101 and/or offset any weakness due to the hole 204. As the electromagnetic shield box 202 is mounted on the same side of the circuit board 101 as the integrated circuit package 104, the circuit board 101 may only require processing on one side, reducing cost and/or complexity. It should be appreciated that such a single-sided circuit board 101 may have a ground plane on a bottom side of the circuit board 101. In some cases, mounting the electromagnetic shield box 202 on the same side of the circuit board 101 as the integrated circuit package 104 may allow the shield box 202 not to extend past the bottom side of the circuit board 101 so that the shield box does not increase the overall height of the system, as shown in FIG. 9. In contrast, a shield mounted on the bottom side of the circuit board 101 may increase the overall height by at least, e.g., 300-400 micrometers. In some embodiments, as described below in more detail, signals may be routed across the electromagnetic shield box 202, allowing signals to be routed under the integrated circuit package 104 even though the circuit board 101 has a hole 204 underneath the integrated circuit package 104.

In an illustrative embodiment, the circuit board 101 is a single-layer circuit board 101 with traces routed on the top surface of the circuit board 101. In some embodiment, the circuit board 101 may have traces routed on both sides of the substrate 102 and/or the circuit board 101 may be a multi-layer circuit board, such as a 2-6 layer circuit board. The substrate 102 may be a fiberglass board made of glass fibers and a resin, such as FR-4. The thickness of the circuit board 101 may be any suitable thickness, such as 100 micrometers to 5 millimeters. The circuit board 101 can have any suitable length and width, such as 5-500 millimeters. Although shown as a rectangle, it should be appreciated that the circuit board 101 may be any suitable shape and may have protrusions, cutouts, etc., in order to accommodate, fit, or touch other components of a device. In the illustrative embodiment, the circuit board 101 is planar. In other embodiments, the circuit board 101 may be non-planar. The hole 204 may be any suitable size, such as a length and/or width of 1-20 millimeters.

The traces 108 may include one or more traces made of copper or other conductor. The traces 108 may carry power signals, carry high-speed input/output, establish ground planes, etc. Traces for power signals may have a width of, e.g., 1-20 millimeters. Each trace 108 on the circuit board may have any suitable width, such as any width from 0.05-20 millimeters. In the illustrative embodiment, signal traces 108 may have a width of 0.1-0.15 millimeters. Each trace 108 on the circuit board may have any suitable height, such as any height from 5 micrometers to 40 micrometers. Vias may extend to and/or from traces 108 through one or more layers of the circuit board 101.

In an illustrative embodiment, some of the traces 108 may be embodied as a differential stripline that can carry high-speed signals. In other embodiments, there may be one high-speed signal trace that carries a signal, and there may be a ground plane or other ground traces near the signal trace. As used herein, a high-speed signal trace 108 refers to a trace 108 that connects two or more circuit components that will transmit and/or receive a signal on the high-speed signal trace at an analog frequency of 100 megahertz or higher. High-speed signal traces 108 may be used for any suitable signal, such as a peripheral component interconnect express (PCIe) interconnect (e.g., a PCIe 6 interconnect), a memory interconnect (such as a DDR or GDDR memory interconnect), a compute express link (CXL) interconnect, a USB interconnect, a display interconnect, etc. It should be appreciated that the electromagnetic shield box 202 may route signals across the hole 204. As a result, the circuit board 101 may have a smaller form factor than it otherwise would without the electromagnetic shield box 202. A smaller form factor may allow for more space for other components, such as a battery, leading to a longer battery life for a device. Additionally or alternatively, the circuit board 101 may have fewer layers than it otherwise would without the electromagnetic shield box 202, as more of the circuit board 101 may be available to use to route high-speed signal traces.

The circuit board 101 may include several other traces or connections not shown in the figures, such as connections between various integrated circuit components 106, 104, such as a processor circuit, a memory circuit, a display circuit, power components, circuit components, etc.

The integrated circuit package 104 may include any suitable component or combination of components, such as one or more processor dies, memory dies, central processing units (CPUs), graphics processing units (CPUs), any other suitable processing units (xPUs), accelerator circuits, a field-programmable gate arrays (FPGA), application-specific integrated circuits (ASICs), etc. In one embodiment, the die 112 on the top of the circuit board 110 is a processor die 112, and the dies 304 are memory dies communicatively coupled to the processor die 112. In some embodiments, the components 304 on the land side of the circuit board 110 may be other circuitry such as capacitors, resistors, inductors, voltage regulators, etc. The integrated circuit package 104 may be connected to contact pads 208 on the circuit board 101 through solder 308. The circuit board 110 may be similar to the circuit board 101, a description of which will not be repeated in the interest of clarity. FIG. 6 shows a view of a bottom of the integrated circuit package 104, showing the dies 304 on the underside of the integrated circuit package 104.

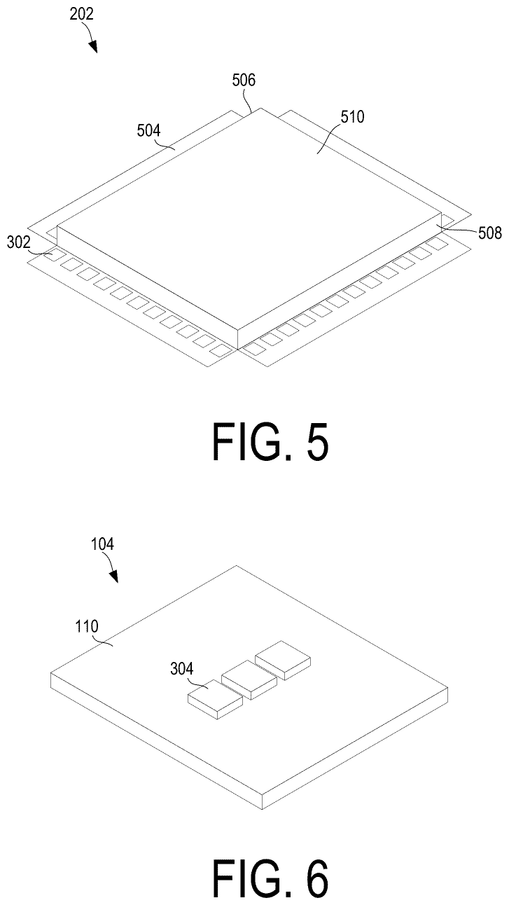

The electromagnetic shield box 202 may be embodied as any suitable material that can at least partially shield electromagnetic interference. The electromagnetic shield box 202 may be a metallic box made from or otherwise include copper, aluminum, silver, gold, or other conductive material. The electromagnetic shield box 202 includes an open box portion 506 that includes a base 410 and four walls 508 connected to the base 410. Tabs 504 are connected to the walls 508, extending parallel to and away from the base 410. Pads 302 are on an underside of the tabs 504. FIG. 5 shows a view of the bottom of the electromagnetic shield box 202. Solder 310 connect the pads 302 on the electromagnetic shield box 202 to the pads 206 on the circuit board 101. Some or all of the pads 206 on the circuit board 101 may be connected to a ground signal or a ground plane, grounding at least part of the electromagnetic shield box 202.

In some embodiments, the electromagnetic shield box 202 may extend past the hole 204, as shown in FIG. 3, increasing the overall height of the system 100. In other embodiments, the electromagnetic shield box 202 does not extend past the hole 204, so the electromagnetic shield box 202 does not increase the overall height of the circuit board 101.

The electromagnetic shield box 202 may have any suitable thickness, such as 0.5-5 millimeters. The box portion 506 may have any suitable length or width, such as 1-20 millimeters. The tabs 504 may have any suitable length of width, such as 1-20 millimeters. The individual segments of the electromagnetic shield box (i.e., the base 410, the sides 508, the tabs 504) may have any suitable thickness, such as 0.1-2 millimeters.

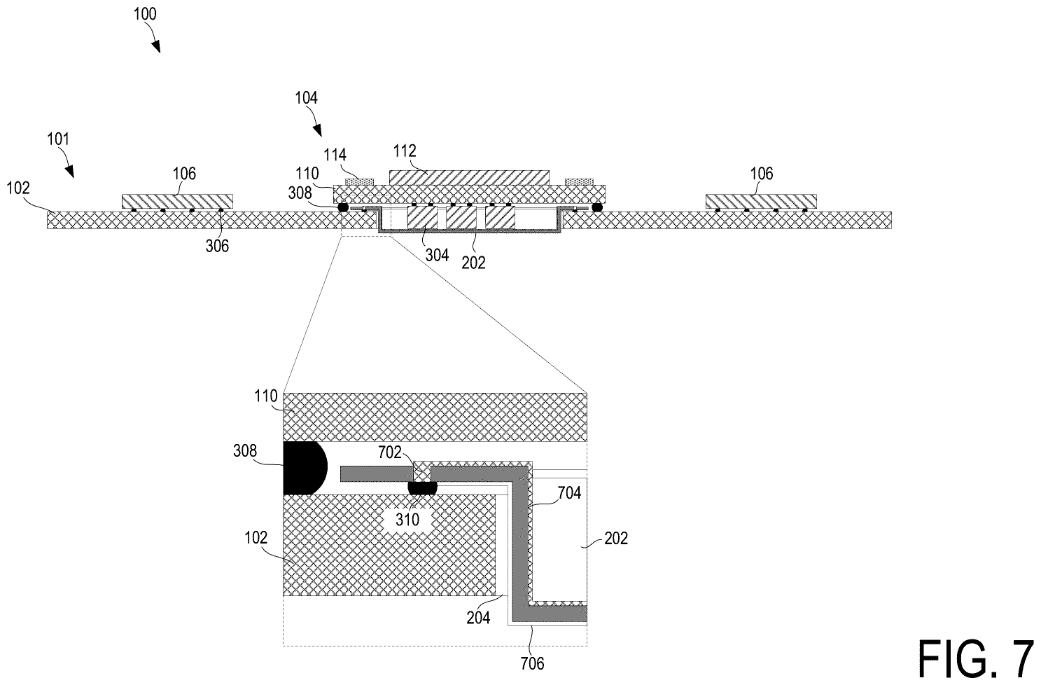

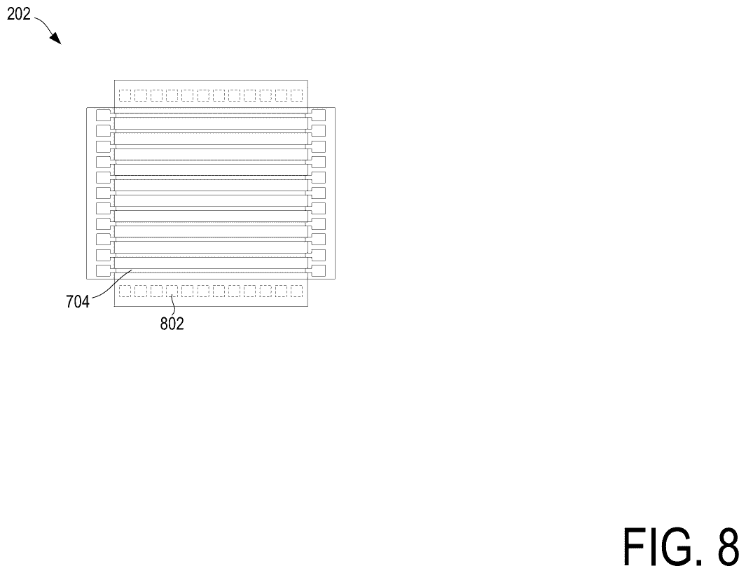

Referring now to FIGS. 7 and 8, in one embodiment, the electromagnetic shield box 202 includes one or more signal traces 704. FIG. 7 shows a cross-sectional view of a system 100 with such an electromagnetic shield box 202, and FIG. 8 shows a top-down view of such an electromagnetic shield box 202. Signal traces 704 may extend along an interior of the electromagnetic shield box 202 and/or signal traces 704 may extend along a buried layer of the electromagnetic shield box 202. The signal traces 704 may be connected to pads 206 on the circuit board 101 through vias 702 in the electromagnetic shield box 202. In some cases, the signal traces 704 may be high-speed traces. In an illustrative embodiment, one or more ground traces 706 may be on some or all of an exterior of the electromagnetic shield 202. The ground traces 706 may be connected to a ground signal or ground plane through, e.g., pads 206. It should be appreciated that the signal traces 704 allow for signals to be carried across the hole 204, potentially reducing the size of the circuit board 101.

In some embodiments, the electromagnetic shield box 202 with one or more signal traces 704 may include a flexible substrate on which conductive material is deposited to form the traces 704, 706. For example, the electromagnetic shield box 202 may be embodied as polyimide polyester, or other flexible substrate.

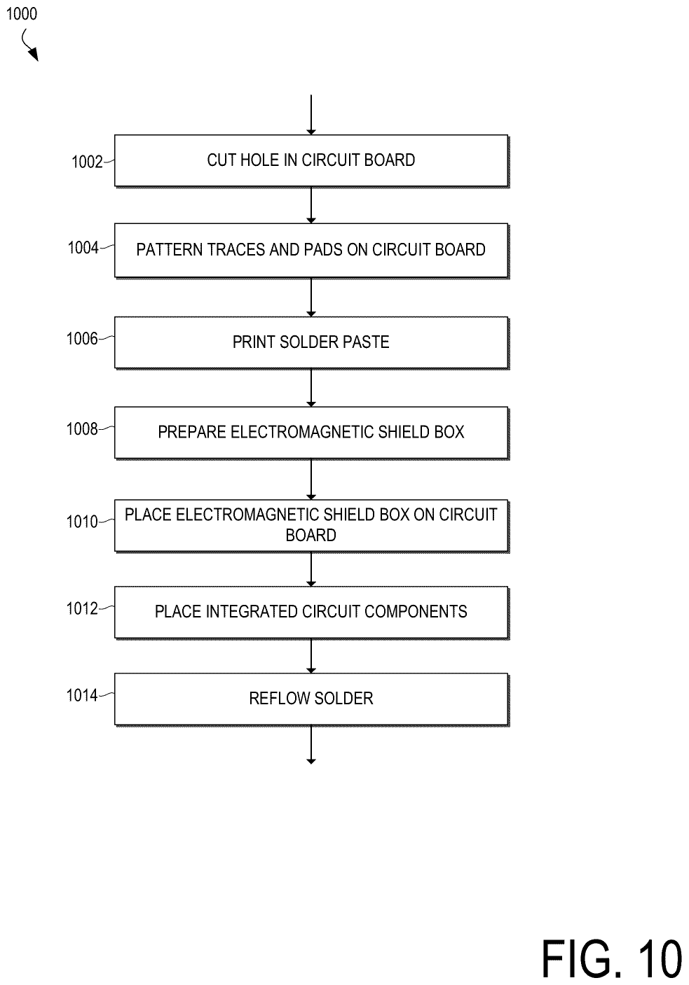

Referring now to FIG. 10, in one embodiment, a flowchart for a method 1000 for creating the system 100 is shown. The method 1000 may be executed by a technician and/or by one or more automated machines. In some embodiments, one or more machines may be programmed to do some or all of the steps of the method 1000. Such a machine may include, e.g., a memory, a processor, data storage, etc. The memory and/or data storage may store instructions that, when executed by the machine, causes the machine to perform some or all of the steps of the method 1000. The method 1000 may use any suitable set of techniques that are used in semiconductor processing or circuit board processing, such as chemical vapor deposition, atomic layer deposition, physical layer deposition, molecular beam epitaxy, layer transfer, photolithography, ion implantation, dry etching, wet etching, selective laser etching, thermal treatments, flip chip, layer transfer, magnetron sputter deposition, pulsed laser deposition, laser machining, 3D photolithography, screen printing, ink jet printing, etc. It should be appreciated that the method 1000 is merely one embodiment of a method to create one embodiment of a system and other methods may be used to create any suitable embodiment of the system. In some embodiments, steps of the method 1000 may be performed in a different order than that shown in the flowchart.

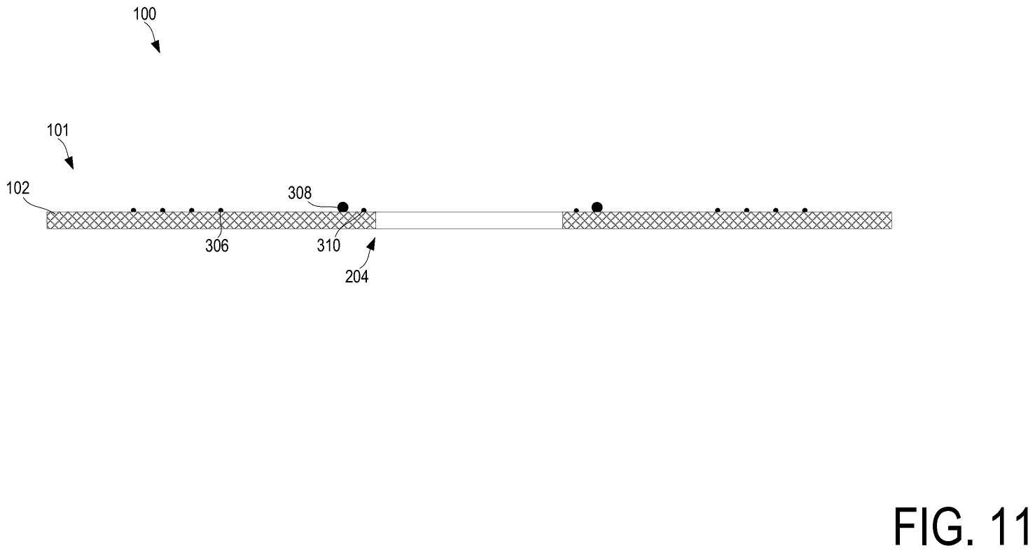

The method 1000 begins in block 1002, in which a hole 204 is cut in a substrate 102 of a circuit board 101. In block 1004, traces 108 and pads 206, 208 are patterned on the circuit board 101. In block 1006, solder paste is deposited on the circuit board 101, as shown in FIG. 11. The solder paste may be placed on contact pads 206, 208 for components such as the integrated circuit package 104 and the electromagnetic shield box 202.

In block 1008, the electromagnetic shield box 202 is prepared. The electromagnetic shield box 202 may be formed from a sheet 1200 of material, as shown in FIG. 12. The sheet 1200 is folded along the dotted lines 1206, creating the electromagnetic shield box 202.

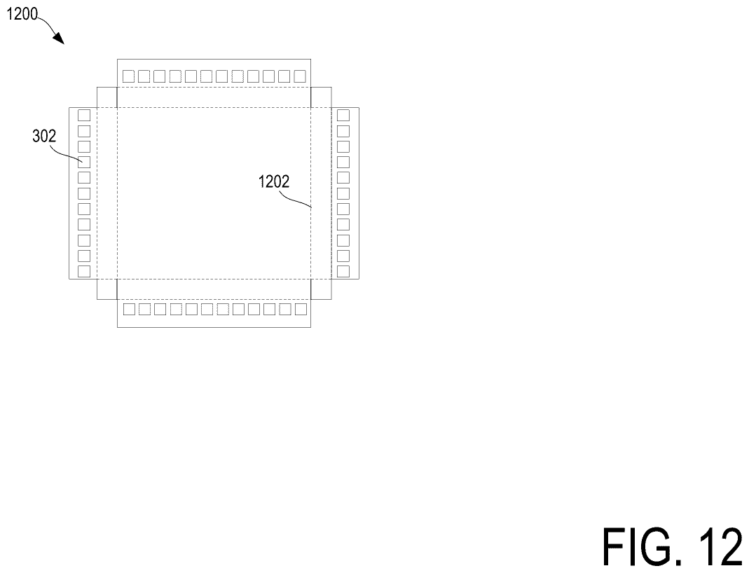

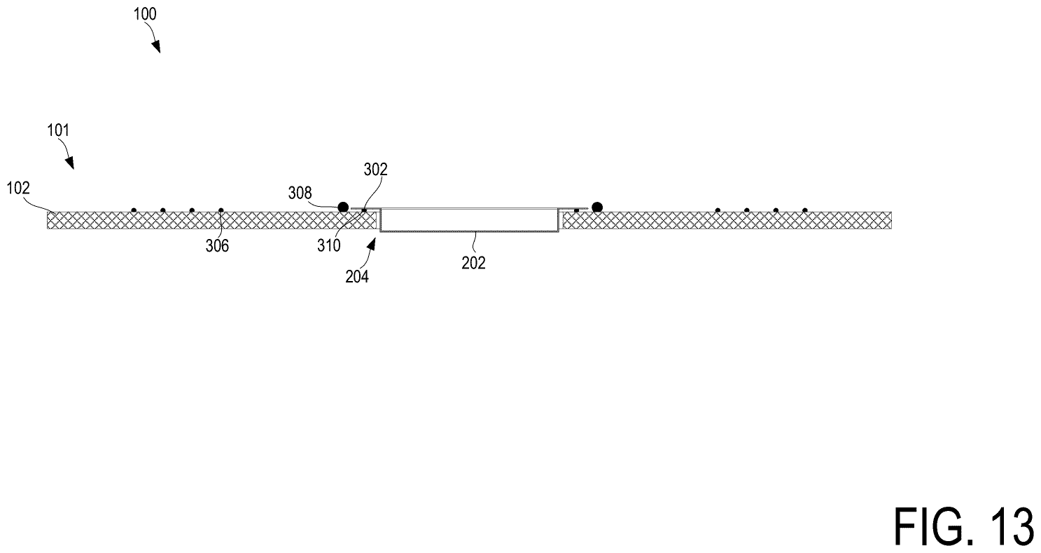

In block 1010, the electromagnetic shield box 202 is mounted on the circuit board 101 in the hole 204, as shown in FIG. 13. In block 1010, the integrated circuit components 104, 106 are placed. In block 1014, the solder is reflowed, bonding the integrated circuit components 104, 106 and electromagnetic shield box 202 to the substrate 102.

It should be appreciated that, in one embodiment, the method 1000 can be performed on one side of the circuit board 101, simplifying the process by not requiring the circuit board 101 to be flipped over or otherwise processed on the backside.

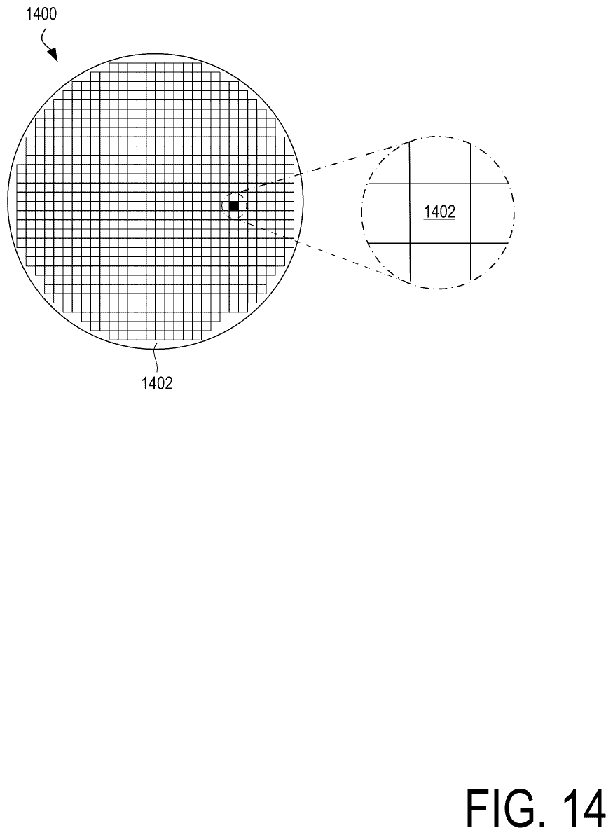

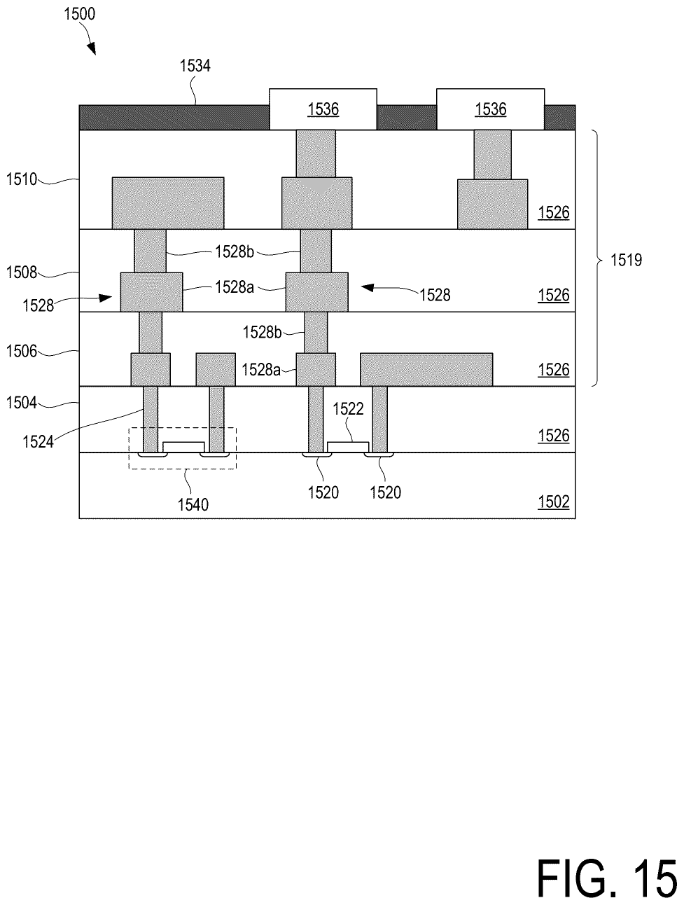

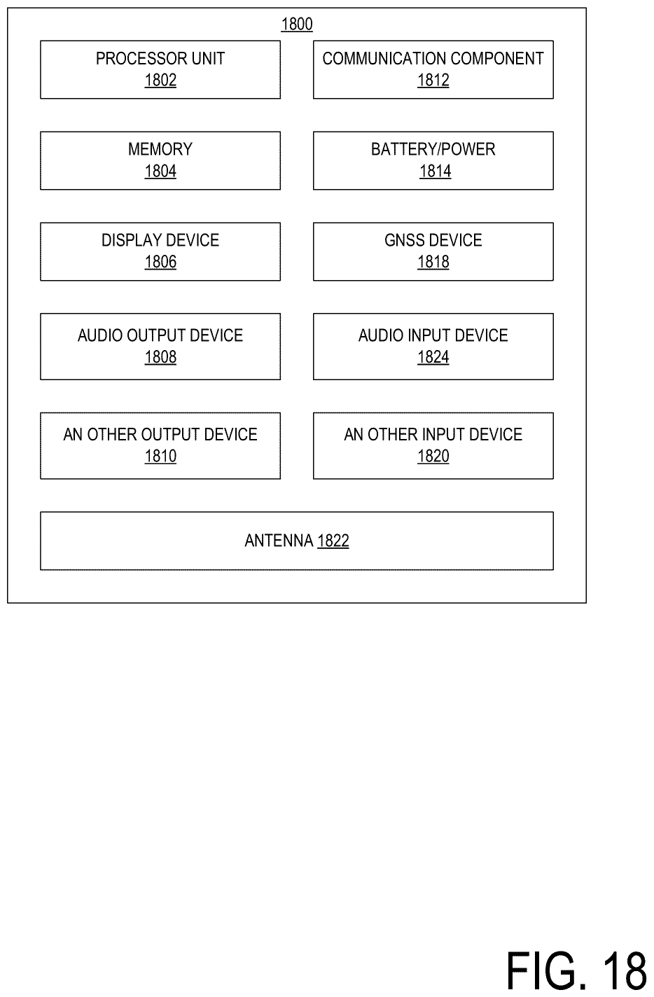

FIG. 14 is a top view of a wafer 1400 and dies 1402 that may be included in any of the systems 100 disclosed herein (e.g., as any suitable ones of the dies 112, 304). The wafer 1400 may be composed of semiconductor material and may include one or more dies 1402 having integrated circuit structures formed on a surface of the wafer 1400. The individual dies 1402 may be a repeating unit of an integrated circuit product that includes any suitable integrated circuit. After the fabrication of the semiconductor product is complete, the wafer 1400 may undergo a singulation process in which the dies 1402 are separated from one another to provide discrete “chips” of the integrated circuit product. The die 1402 may be any of the dies 112, 304 disclosed herein. The die 1402 may include one or more transistors (e.g., some of the transistors 1540 of FIG. 15, discussed below), supporting circuitry to route electrical signals to the transistors, passive components (e.g., signal traces, resistors, capacitors, or inductors), and/or any other integrated circuit components. In some embodiments, the wafer 1400 or the die 1402 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1402. For example, a memory array formed by multiple memory devices may be formed on a same die 1402 as a processor unit (e.g., the processor unit 1802 of FIG. 18) or other logic that is configured to store information in the memory devices or execute instructions stored in the memory array. Various ones of the systems 100 disclosed herein may be manufactured using a die-to-wafer assembly technique in which some dies 112, 304 are attached to a wafer 1400 that include others of the dies 112, 304, and the wafer 1400 is subsequently singulated.

FIG. 15 is a cross-sectional side view of an integrated circuit device 1500 that may be included in any of the systems 100 disclosed herein (e.g., in any of the dies 112, 304). One or more of the integrated circuit devices 1500 may be included in one or more dies 1402 (FIG. 14). The integrated circuit device 1500 may be formed on a die substrate 1502 (e.g., the wafer 1400 of FIG. 14) and may be included in a die (e.g., the die 1402 of FIG. 14). The die substrate 1502 may be a semiconductor substrate composed of semiconductor material systems including, for example, n-type or p-type materials systems (or a combination of both). The die substrate 1502 may include, for example, a crystalline substrate formed using a bulk silicon or a silicon-on-insulator (SOI) substructure. In some embodiments, the die substrate 1502 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 1502. Although a few examples of materials from which the die substrate 1502 may be formed are described here, any material that may serve as a foundation for an integrated circuit device 1500 may be used. The die substrate 1502 may be part of a singulated die (e.g., the dies 1402 of FIG. 14) or a wafer (e.g., the wafer 1400 of FIG. 14).

The integrated circuit device 1500 may include one or more device layers 1504 disposed on the die substrate 1502. The device layer 1504 may include features of one or more transistors 1540 (e.g., metal oxide semiconductor field-effect transistors (MOSFETs)) formed on the die substrate 1502. The transistors 1540 may include, for example, one or more source and/or drain (S/D) regions 1520, a gate 1522 to control current flow between the S/D regions 1520, and one or more S/D contacts 1524 to route electrical signals to/from the S/D regions 1520. The transistors 1540 may include additional features not depicted for the sake of clarity, such as device isolation regions, gate contacts, and the like. The transistors 1540 are not limited to the type and configuration depicted in FIG. 15 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

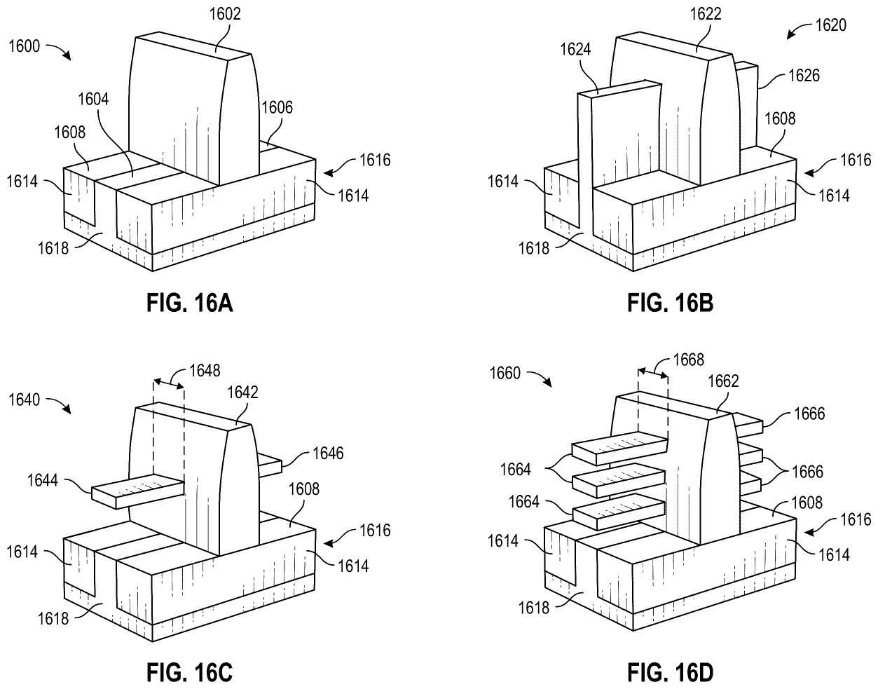

FIGS. 16A-16D are simplified perspective views of example planar, FinFET, gate-all-around, and stacked gate-all-around transistors. The transistors illustrated in FIGS. 16A-16D are formed on a substrate 1616 having a surface 1608. Isolation regions 1614 separate the source and drain regions of the transistors from other transistors and from a bulk region 1618 of the substrate 1616.

FIG. 16A is a perspective view of an example planar transistor 1600 comprising a gate 1602 that controls current flow between a source region 1604 and a drain region 1606. The transistor 1600 is planar in that the source region 1604 and the drain region 1606 are planar with respect to the substrate surface 1608.

FIG. 16B is a perspective view of an example FinFET transistor 1620 comprising a gate 1622 that controls current flow between a source region 1624 and a drain region 1626. The transistor 1620 is non-planar in that the source region 1624 and the drain region 1626 comprise “fins” that extend upwards from the substrate surface 1628. As the gate 1622 encompasses three sides of the semiconductor fin that extends from the source region 1624 to the drain region 1626, the transistor 1620 can be considered a tri-gate transistor. FIG. 16B illustrates one S/D fin extending through the gate 1622, but multiple S/D fins can extend through the gate of a FinFET transistor.

FIG. 16C is a perspective view of a gate-all-around (GAA) transistor 1640 comprising a gate 1642 that controls current flow between a source region 1644 and a drain region 1646. The transistor 1640 is non-planar in that the source region 1644 and the drain region 1646 are elevated from the substrate surface 1628.

FIG. 16D is a perspective view of a GAA transistor 1660 comprising a gate 1662 that controls current flow between multiple elevated source regions 1664 and multiple elevated drain regions 1666. The transistor 1660 is a stacked GAA transistor as the gate controls the flow of current between multiple elevated S/D regions stacked on top of each other. The transistors 1640 and 1660 are considered gate-all-around transistors as the gates encompass all sides of the semiconductor portions that extends from the source regions to the drain regions. The transistors 1640 and 1660 can alternatively be referred to as nanowire, nanosheet, or nanoribbon transistors depending on the width (e.g., widths 1648 and 1668 of transistors 1640 and 1660, respectively) of the semiconductor portions extending through the gate.

Returning to FIG. 15, a transistor 1540 may include a gate 1522 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 1540 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1540 along the source-channel-drain direction, the gate electrode may consist of a U-shaped structure that includes a bottom portion substantially parallel to the surface of the die substrate 1502 and two sidewall portions that are substantially perpendicular to the top surface of the die substrate 1502. In other embodiments, at least one of the metal layers that form the gate electrode may simply be a planar layer that is substantially parallel to the top surface of the die substrate 1502 and does not include sidewall portions substantially perpendicular to the top surface of the die substrate 1502. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1520 may be formed within the die substrate 1502 adjacent to the gate 1522 of individual transistors 1540. The S/D regions 1520 may be formed using an implantation/diffusion process or an etching/deposition process, for example. In the former process, dopants such as boron, aluminum, antimony, phosphorous, or arsenic may be ion-implanted into the die substrate 1502 to form the S/D regions 1520. An annealing process that activates the dopants and causes them to diffuse farther into the die substrate 1502 may follow the ion-implantation process. In the latter process, the die substrate 1502 may first be etched to form recesses at the locations of the S/D regions 1520. An epitaxial deposition process may then be carried out to fill the recesses with material that is used to fabricate the S/D regions 1520. In some implementations, the S/D regions 1520 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1520 may be formed using one or more alternate semiconductor materials such as germanium or a group III-V material or alloy. In further embodiments, one or more layers of metal and/or metal alloys may be used to form the S/D regions 1520.

Electrical signals, such as power and/or input/output (I/O) signals, may be routed to and/or from the devices (e.g., transistors 1540) of the device layer 1504 through one or more interconnect layers disposed on the device layer 1504 (illustrated in FIG. 15 as interconnect layers 1506-1510). For example, electrically conductive features of the device layer 1504 (e.g., the gate 1522 and the S/D contacts 1524) may be electrically coupled with the interconnect structures 1528 of the interconnect layers 1506-1510. The one or more interconnect layers 1506-1510 may form a metallization stack (also referred to as an “ILD stack”) 1519 of the integrated circuit device 1500.

The interconnect structures 1528 may be arranged within the interconnect layers 1506-1510 to route electrical signals according to a wide variety of designs; in particular, the arrangement is not limited to the particular configuration of interconnect structures 1528 depicted in FIG. 15. Although a particular number of interconnect layers 1506-1510 is depicted in FIG. 15, embodiments of the present disclosure include integrated circuit devices having more or fewer interconnect layers than depicted.

In some embodiments, the interconnect structures 1528 may include lines 1528a and/or vias 1528b filled with an electrically conductive material such as a metal. The lines 1528a may be arranged to route electrical signals in a direction of a plane that is substantially parallel with a surface of the die substrate 1502 upon which the device layer 1504 is formed. For example, the lines 1528a may route electrical signals in a direction in and out of the page and/or in a direction across the page. The vias 1528b may be arranged to route electrical signals in a direction of a plane that is substantially perpendicular to the surface of the die substrate 1502 upon which the device layer 1504 is formed. In some embodiments, the vias 1528b may electrically couple lines 1528a of different interconnect layers 1506-1510 together.

The interconnect layers 1506-1510 may include a dielectric material 1526 disposed between the interconnect structures 1528, as shown in FIG. 15. In some embodiments, dielectric material 1526 disposed between the interconnect structures 1528 in different ones of the interconnect layers 1506-1510 may have different compositions; in other embodiments, the composition of the dielectric material 1526 between different interconnect layers 1506-1510 may be the same. The device layer 1504 may include a dielectric material 1526 disposed between the transistors 1540 and a bottom layer of the metallization stack as well. The dielectric material 1526 included in the device layer 1504 may have a different composition than the dielectric material 1526 included in the interconnect layers 1506-1510; in other embodiments, the composition of the dielectric material 1526 in the device layer 1504 may be the same as a dielectric material 1526 included in any one of the interconnect layers 1506-1510.

A first interconnect layer 1506 (referred to as Metal 1 or “M1”) may be formed directly on the device layer 1504. In some embodiments, the first interconnect layer 1506 may include lines 1528a and/or vias 1528b, as shown. The lines 1528a of the first interconnect layer 1506 may be coupled with contacts (e.g., the S/D contacts 1524) of the device layer 1504. The vias 1528b of the first interconnect layer 1506 may be coupled with the lines 1528a of a second interconnect layer 1508.

The second interconnect layer 1508 (referred to as Metal 2 or “M2”) may be formed directly on the first interconnect layer 1506. In some embodiments, the second interconnect layer 1508 may include via 1528b to couple the lines 1528 of the second interconnect layer 1508 with the lines 1528a of a third interconnect layer 1510. Although the lines 1528a and the vias 1528b are structurally delineated with a line within individual interconnect layers for the sake of clarity, the lines 1528a and the vias 1528b may be structurally and/or materially contiguous (e.g., simultaneously filled during a dual-damascene process) in some embodiments.

The third interconnect layer 1510 (referred to as Metal 3 or “M3”) (and additional interconnect layers, as desired) may be formed in succession on the second interconnect layer 1508 according to similar techniques and configurations described in connection with the second interconnect layer 1508 or the first interconnect layer 1506. In some embodiments, the interconnect layers that are “higher up” in the metallization stack 1519 in the integrated circuit device 1500 (i.e., farther away from the device layer 1504) may be thicker that the interconnect layers that are lower in the metallization stack 1519, with lines 1528a and vias 1528b in the higher interconnect layers being thicker than those in the lower interconnect layers.

The integrated circuit device 1500 may include a solder resist material 1534 (e.g., polyimide or similar material) and one or more conductive contacts 1536 formed on the interconnect layers 1506-1510. In FIG. 15, the conductive contacts 1536 are illustrated as taking the form of bond pads. The conductive contacts 1536 may be electrically coupled with the interconnect structures 1528 and configured to route the electrical signals of the transistor(s) 1540 to external devices. For example, solder bonds may be formed on the one or more conductive contacts 1536 to mechanically and/or electrically couple an integrated circuit die including the integrated circuit device 1500 with another component (e.g., a printed circuit board). The integrated circuit device 1500 may include additional or alternate structures to route the electrical signals from the interconnect layers 1506-1510; for example, the conductive contacts 1536 may include other analogous features (e.g., posts) that route the electrical signals to external components.

In some embodiments in which the integrated circuit device 1500 is a double-sided die, the integrated circuit device 1500 may include another metallization stack (not shown) on the opposite side of the device layer(s) 1504. This metallization stack may include multiple interconnect layers as discussed above with reference to the interconnect layers 1506-1510, to provide conductive pathways (e.g., including conductive lines and vias) between the device layer(s) 1504 and additional conductive contacts (not shown) on the opposite side of the integrated circuit device 1500 from the conductive contacts 1536.

In other embodiments in which the integrated circuit device 1500 is a double-sided die, the integrated circuit device 1500 may include one or more through silicon vias (TSVs) through the die substrate 1502; these TSVs may make contact with the device layer(s) 1504, and may provide conductive pathways between the device layer(s) 1504 and additional conductive contacts (not shown) on the opposite side of the integrated circuit device 1500 from the conductive contacts 1536. In some embodiments, TSVs extending through the substrate can be used for routing power and ground signals from conductive contacts on the opposite side of the integrated circuit device 1500 from the conductive contacts 1536 to the transistors 1540 and any other components integrated into the die 1500, and the metallization stack 1519 can be used to route I/O signals from the conductive contacts 1536 to transistors 1540 and any other components integrated into the die 1500.

Multiple integrated circuit devices 1500 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

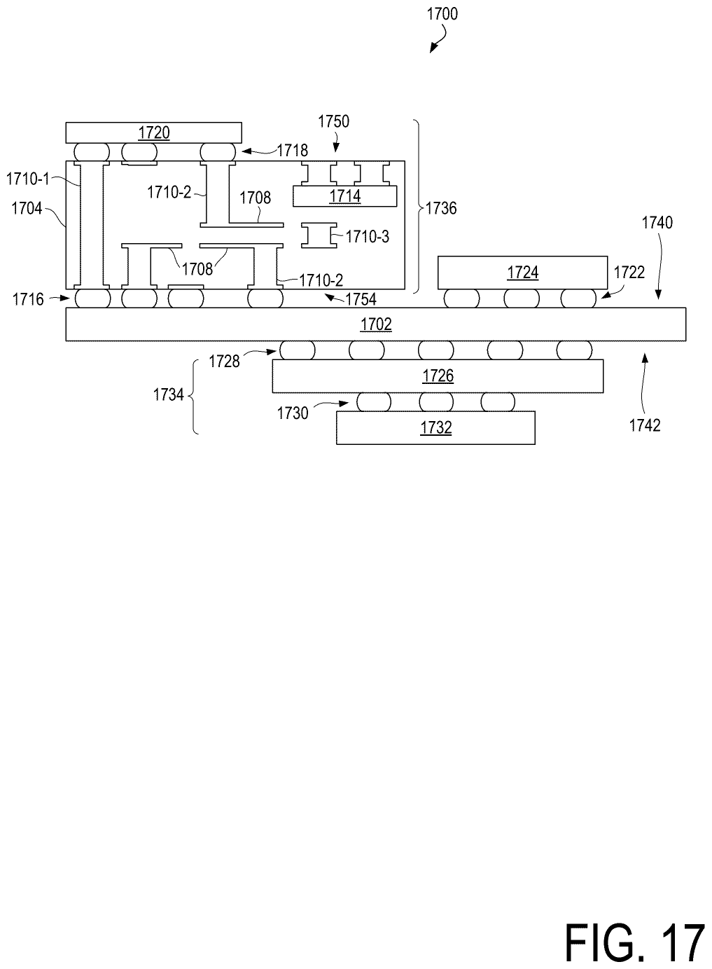

FIG. 17 is a cross-sectional side view of an integrated circuit device assembly 1700 that may include any of the systems 100 disclosed herein. The integrated circuit device assembly 1700 includes a number of components disposed on a circuit board 1702 (which may be a motherboard, system board, mainboard, etc.). The integrated circuit device assembly 1700 includes components disposed on a first face 1740 of the circuit board 1702 and an opposing second face 1742 of the circuit board 1702; generally, components may be disposed on one or both faces 1740 and 1742. Any of the integrated circuit components discussed below with reference to the integrated circuit device assembly 1700 may take the form of any suitable ones of the embodiments of the systems 100 disclosed herein.

In some embodiments, the circuit board 1702 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate. In some embodiments the circuit board 1702 may be, for example, the circuit board 101 or 110. The integrated circuit device assembly 1700 illustrated in FIG. 17 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702, and may include solder balls (as shown in FIG. 17), pins (e.g., as part of a pin grid array (PGA), contacts (e.g., as part of a land grid array (LGA)), male and female portions of a socket, an adhesive, an underfill material, and/or any other suitable electrical and/or mechanical coupling structure. The coupling components 1716 may serve as the coupling components illustrated or described for any of the substrate assembly or substrate assembly components described herein, as appropriate.

The package-on-interposer structure 1736 may include an integrated circuit component 1720 coupled to an interposer 1704 by coupling components 1718. The coupling components 1718 may take any suitable form for the application, such as the forms discussed above with reference to the coupling components 1716. Although a single integrated circuit component 1720 is shown in FIG. 17, multiple integrated circuit components may be coupled to the interposer 1704; indeed, additional interposers may be coupled to the interposer 1704. The interposer 1704 may provide an intervening substrate used to bridge the circuit board 1702 and the integrated circuit component 1720.

The integrated circuit component 1720 may be a packaged or unpacked integrated circuit product that includes one or more integrated circuit dies (e.g., the die 1402 of FIG. 14, the integrated circuit device 1500 of FIG. 15) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 1720, a single monolithic integrated circuit die comprises solder bumps attached to contacts on the die. The solder bumps allow the die to be directly attached to the interposer 1704. The integrated circuit component 1720 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 1720 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 1720 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 1720 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 1704 may spread connections to a wider pitch or reroute a connection to a different connection. For example, the interposer 1704 may couple the integrated circuit component 1720 to a set of ball grid array (BGA) conductive contacts of the coupling components 1716 for coupling to the circuit board 1702. In the embodiment illustrated in FIG. 17, the integrated circuit component 1720 and the circuit board 1702 are attached to opposing sides of the interposer 1704; in other embodiments, the integrated circuit component 1720 and the circuit board 1702 may be attached to a same side of the interposer 1704. In some embodiments, three or more components may be interconnected by way of the interposer 1704.

In some embodiments, the interposer 1704 may be formed as a PCB, including multiple metal layers separated from one another by layers of dielectric material and interconnected by electrically conductive vias. In some embodiments, the interposer 1704 may be formed of an epoxy resin, a fiberglass-reinforced epoxy resin, an epoxy resin with inorganic fillers, a ceramic material, or a polymer material such as polyimide. In some embodiments, the interposer 1704 may be formed of alternate rigid or flexible materials that may include the same materials described above for use in a semiconductor substrate, such as silicon, germanium, and other group III-V and group IV materials. The interposer 1704 may include metal interconnects 1708 and vias 1710, including but not limited to through hole vias 1710-1 (that extend from a first face 1750 of the interposer 1704 to a second face 1754 of the interposer 1704), blind vias 1710-2 (that extend from the first or second faces 1750 or 1754 of the interposer 1704 to an internal metal layer), and buried vias 1710-3 (that connect internal metal layers).

In some embodiments, the interposer 1704 can comprise a silicon interposer. Through silicon vias (TSV) extending through the silicon interposer can connect connections on a first face of a silicon interposer to an opposing second face of the silicon interposer. In some embodiments, an interposer 1704 comprising a silicon interposer can further comprise one or more routing layers to route connections on a first face of the interposer 1704 to an opposing second face of the interposer 1704.

The interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1704. The package-on-interposer structure 1736 may take the form of any of the package-on-interposer structures known in the art.

The integrated circuit device assembly 1700 may include an integrated circuit component 1724 coupled to the first face 1740 of the circuit board 1702 by coupling components 1722. The coupling components 1722 may take the form of any of the embodiments discussed above with reference to the coupling components 1716, and the integrated circuit component 1724 may take the form of any of the embodiments discussed above with reference to the integrated circuit component 1720.

The integrated circuit device assembly 1700 illustrated in FIG. 17 includes a package-on-package structure 1734 coupled to the second face 1742 of the circuit board 1702 by coupling components 1728. The package-on-package structure 1734 may include an integrated circuit component 1726 and an integrated circuit component 1732 coupled together by coupling components 1730 such that the integrated circuit component 1726 is disposed between the circuit board 1702 and the integrated circuit component 1732. The coupling components 1728 and 1730 may take the form of any of the embodiments of the coupling components 1716 discussed above, and the integrated circuit components 1726 and 1732 may take the form of any of the embodiments of the integrated circuit component 1720 discussed above. The package-on-package structure 1734 may be configured in accordance with any of the package-on-package structures known in the art.

FIG. 18 is a block diagram of an example electrical device 1800 that may include one or more of the systems 100 disclosed herein. For example, any suitable ones of the components of the electrical device 1800 may include one or more of the integrated circuit device assemblies 1700, integrated circuit components 1720, integrated circuit devices 1500, or integrated circuit dies 1402 disclosed herein, and may be arranged in any of the systems 100 disclosed herein. A number of components are illustrated in FIG. 18 as included in the electrical device 1800, but any one or more of these components may be omitted or duplicated, as suitable for the application. In some embodiments, some or all of the components included in the electrical device 1800 may be attached to one or more motherboards mainboards, or system boards. In some embodiments, one or more of these components are fabricated onto a single system-on-a-chip (SoC) die.

Additionally, in various embodiments, the electrical device 1800 may not include one or more of the components illustrated in FIG. 18, but the electrical device 1800 may include interface circuitry for coupling to the one or more components. For example, the electrical device 1800 may not include a display device 1806, but may include display device interface circuitry (e.g., a connector and driver circuitry) to which a display device 1806 may be coupled. In another set of examples, the electrical device 1800 may not include an audio input device 1824 or an audio output device 1808, but may include audio input or output device interface circuitry (e.g., connectors and supporting circuitry) to which an audio input device 1824 or audio output device 1808 may be coupled.

The electrical device 1800 may include one or more processor units 1802 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1802 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1800 may include a memory 1804, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1804 may include memory that is located on the same integrated circuit die as the processor unit 1802. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 1800 can comprise one or more processor units 1802 that are heterogeneous or asymmetric to another processor unit 1802 in the electrical device 1800. There can be a variety of differences between the processing units 1802 in a system in terms of a spectrum of metrics of merit including architectural, microarchitectural, thermal, power consumption characteristics, and the like. These differences can effectively manifest themselves as asymmetry and heterogeneity among the processor units 1802 in the electrical device 1800.

In some embodiments, the electrical device 1800 may include a communication component 1812 (e.g., one or more communication components). For example, the communication component 1812 can manage wireless communications for the transfer of data to and from the electrical device 1800. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1812 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1812 may operate in accordance with other wireless protocols in other embodiments. The electrical device 1800 may include an antenna 1822 to facilitate wireless communications and/or to receive other wireless communications (such as AM or FM radio transmissions).

In some embodiments, the communication component 1812 may manage wired communications, such as electrical, optical, or any other suitable communication protocols (e.g., IEEE 802.3 Ethernet standards). As noted above, the communication component 1812 may include multiple communication components. For instance, a first communication component 1812 may be dedicated to shorter-range wireless communications such as Wi-Fi or Bluetooth, and a second communication component 1812 may be dedicated to longer-range wireless communications such as global positioning system (GPS), EDGE, GPRS, CDMA, WiMAX, LTE, EV-DO, or others. In some embodiments, a first communication component 1812 may be dedicated to wireless communications, and a second communication component 1812 may be dedicated to wired communications.

The electrical device 1800 may include battery/power circuitry 1814. The battery/power circuitry 1814 may include one or more energy storage devices (e.g., batteries or capacitors) and/or circuitry for coupling components of the electrical device 1800 to an energy source separate from the electrical device 1800 (e.g., AC line power).

The electrical device 1800 may include a display device 1806 (or corresponding interface circuitry, as discussed above). The display device 1806 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1800 may include an audio output device 1808 (or corresponding interface circuitry, as discussed above). The audio output device 1808 may include any embedded or wired or wirelessly connected external device that generates an audible indicator, such as speakers, headsets, or earbuds.

The electrical device 1800 may include an audio input device 1824 (or corresponding interface circuitry, as discussed above). The audio input device 1824 may include any embedded or wired or wirelessly connected device that generates a signal representative of a sound, such as microphones, microphone arrays, or digital instruments (e.g., instruments having a musical instrument digital interface (MIDI) output). The electrical device 1800 may include a Global Navigation Satellite System (GNSS) device 1818 (or corresponding interface circuitry, as discussed above), such as a Global Positioning System (GPS) device. The GNSS device 1818 may be in communication with a satellite-based system and may determine a geolocation of the electrical device 1800 based on information received from one or more GNSS satellites, as known in the art.

The electrical device 1800 may include an other output device 1810 (or corresponding interface circuitry, as discussed above). Examples of the other output device 1810 may include an audio codec, a video codec, a printer, a wired or wireless transmitter for providing information to other devices, or an additional storage device.

The electrical device 1800 may include an other input device 1820 (or corresponding interface circuitry, as discussed above). Examples of the other input device 1820 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1800 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1800 may be any other electronic device that processes data. In some embodiments, the electrical device 1800 may comprise multiple discrete physical components. Given the range of devices that the electrical device 1800 can be manifested as in various embodiments, in some embodiments, the electrical device 1800 can be referred to as a computing device or a computing system.

### EXAMPLES

Illustrative examples of the technologies disclosed herein are provided below. An embodiment of the technologies may include any one or more, and any combination of, the examples described below.

Example 1 includes a circuit board comprising a substrate comprising a top surface and a bottom surface, wherein a hole is defined in the substrate, wherein the hole extends from the top surface to the bottom surface; a plurality of pads on the top surface of the substrate; and an electromagnetic shield box, wherein the electromagnetic shield box is at least partially disposed in the hole, wherein the electromagnetic shield box comprises one or more tabs, wherein the one or more tabs mate with one or more of the plurality of pads on the top surface of the substrate.

Example 2 includes a system comprising the circuit board of Example 1, further comprising an integrated circuit package mounted on the top surface of the substrate, the integrated circuit package comprising a circuit board, the circuit board of the integrated circuit package comprising a top surface and a bottom surface; a first die mounted on the top surface of the circuit board of the integrated circuit package; and a second die mounted on the bottom surface of the circuit board of the integrated circuit package, wherein the second die is at least partially disposed in the hole.

Example 3 includes the subject matter of Example 2, and wherein the first die is a processor die, wherein the second die is a memory die.

Example 4 includes the subject matter of any of Examples 2 and 3, and wherein the circuit board is a single-sided circuit board.

Example 5 includes the subject matter of any of Examples 2-4, and wherein the electromagnetic shield box comprises one or more signal traces and one or more ground traces, wherein the one or more signal traces carry one or more signals from one side of the hole in the substrate to an opposite side of the hole in the substrate.

Example 6 includes the subject matter of any of Examples 2-5, and wherein the electromagnetic shield box comprises a flexible substrate.

Example 7 includes the subject matter of any of Examples 2-6, and wherein the electromagnetic shield box comprises one or more vias, wherein the one or more vias couple the one or more signal traces to one or more of the plurality of pads.

Example 8 includes the subject matter of any of Examples 2-7, and wherein the electromagnetic shield box is rigid.

Example 9 includes the subject matter of any of Examples 2-8, and wherein the electromagnetic shield box does not extend below the bottom surface of the circuit board.

Example 10 includes the subject matter of any of Examples 2-9, and wherein the electromagnetic shield box comprises copper.

Example 11 includes a method comprising processing a top side of a substrate to form a circuit board, wherein the substrate comprises a top surface and a bottom surface, wherein a hole is defined in the substrate, wherein the hole extends from the top surface to the bottom surface, wherein processing the top side of the substrate comprises forming a plurality of pads on the top surface of the substrate; disposing an electromagnetic shield box at least partially in the hole; and connecting the electromagnetic shield box to one or more of the plurality of pads using solder.

Example 12 includes the subject matter of Example 11, and wherein processing the top side of the substrate comprises forming a second plurality of pads on the top surface of the substrate; and connecting an integrated circuit package to the second plurality of pads using solder.

Example 13 includes the subject matter of any of Examples 11 and 12, and further including mounting an integrated circuit package on the top surface of the substrate, the integrated circuit package comprising a circuit board, the circuit board of the integrated circuit package comprising a top surface and a bottom surface; a first die mounted on the top surface of the circuit board of the integrated circuit package; and a second die mounted on the bottom surface of the circuit board of the integrated circuit package, wherein the second die is at least partially disposed in the hole.

Example 14 includes the subject matter of any of Examples 11-13, and wherein the first die is a processor die, wherein the second die is a memory die.

Example 15 includes the subject matter of any of Examples 11-14, and wherein the circuit board is a single-sided circuit board.

Example 16 includes the subject matter of any of Examples 11-15, and wherein the electromagnetic shield box comprises one or more signal traces and one or more ground traces, wherein the one or more signal traces carry one or more signals from one side of the hole in the substrate to an opposite side of the hole in the substrate.

Example 17 includes the subject matter of any of Examples 11-16, and wherein the electromagnetic shield box comprises a flexible substrate.

Example 18 includes the subject matter of any of Examples 11-17, and wherein the electromagnetic shield box comprises one or more vias, wherein the one or more vias couple the one or more signal traces to one or more of the plurality of pads.

Example 19 includes the subject matter of any of Examples 11-18, and wherein the electromagnetic shield box is rigid.

Example 20 includes the subject matter of any of Examples 11-19, and wherein the electromagnetic shield box does not extend below the bottom surface of the circuit board.

Example 21 includes the subject matter of any of Examples 11-20, and wherein the electromagnetic shield box comprises copper.

Example 22 includes a circuit board comprising a substrate comprising a top surface and a bottom surface, wherein a hole is defined in the substrate, wherein the hole extends from the top surface to the bottom surface; a plurality of pads on the top surface of the substrate; and means for shielding one or more components mounted on the circuit board, wherein the means for shielding is at least partially disposed in the hole, wherein the means for shielding mates with one or more of the plurality of pads on the top surface of the substrate.

Example 23 includes a system comprising the circuit board of Example 22, further comprising an integrated circuit package mounted on the top surface of the substrate, the integrated circuit package comprising a circuit board, the circuit board of the integrated circuit package comprising a top surface and a bottom surface; a first die mounted on the top surface of the circuit board of the integrated circuit package; and a second die mounted on the bottom surface of the circuit board of the integrated circuit package, wherein the second die is at least partially disposed in the hole.

Example 24 includes the subject matter of Example 23, and wherein the first die is a processor die, wherein the second die is a memory die.

Example 25 includes the subject matter of any of Examples 23 and 24, and wherein the circuit board is a single-sided circuit board.

Example 26 includes the subject matter of any of Examples 23-25, and wherein the means for shielding comprises one or more signal traces and one or more ground traces, wherein the one or more signal traces carry one or more signals from one side of the hole in the substrate to an opposite side of the hole in the substrate.

Example 27 includes the subject matter of any of Examples 23-26, and wherein the means for shielding comprises a flexible substrate.

Example 28 includes the subject matter of any of Examples 23-27, and wherein the means for shielding comprises one or more vias, wherein the one or more vias couple the one or more signal traces to one or more of the plurality of pads.

Example 29 includes the subject matter of any of Examples 23-28, and wherein the means for shielding is rigid.

Example 30 includes the subject matter of any of Examples 23-29, and wherein the means for shielding does not extend below the bottom surface of the circuit board.

Example 31 includes the subject matter of any of Examples 23-30, and wherein the means for shielding comprises copper.

1. A circuit board comprising:
a substrate comprising a top surface and a bottom surface, wherein a hole is defined in the substrate, wherein the hole extends from the top surface to the bottom surface;
a plurality of pads on the top surface of the substrate; and
a metallic box,
wherein the metallic box is at least partially disposed in the hole,
wherein the metallic box comprises one or more tabs,
wherein the one or more tabs mate with one or more of the plurality of pads on the top surface of the substrate.

2. A system comprising the circuit board of claim 1, further comprising an integrated circuit package mounted on the top surface of the substrate, the integrated circuit package comprising:
a circuit board, the circuit board of the integrated circuit package comprising a top surface and a bottom surface;
a first die mounted on the top surface of the circuit board of the integrated circuit package; and
a second die mounted on the bottom surface of the circuit board of the integrated circuit package, wherein the second die is at least partially disposed in the hole.

3. The system of claim 2, wherein the first die is a processor die, wherein the second die is a memory die.

4. The circuit board of claim 1, wherein the circuit board is a single-sided circuit board.

5. The circuit board of claim 1, wherein the metallic box does not extend below the bottom surface of the circuit board.

6. The circuit board of claim 1, wherein the metallic box comprises copper.

7. A method comprising:
processing a top side of a substrate to form a circuit board, wherein the substrate comprises a top surface and a bottom surface, wherein a hole is defined in the substrate, wherein the hole extends from the top surface to the bottom surface, wherein processing the top side of the substrate comprises:
forming a plurality of pads on the top surface of the substrate;
disposing an electromagnetic shield box at least partially in the hole; and
connecting the electromagnetic shield box to one or more of the plurality of pads using solder.

8. The method of claim 7, wherein processing the top side of the substrate comprises:
forming a second plurality of pads on the top surface of the substrate; and
connecting an integrated circuit package to the second plurality of pads using solder.

9. The method of claim 7, further comprising mounting an integrated circuit package on the top surface of the substrate, the integrated circuit package comprising:
a circuit board, the circuit board of the integrated circuit package comprising a top surface and a bottom surface;
a first die mounted on the top surface of the circuit board of the integrated circuit package; and
a second die mounted on the bottom surface of the circuit board of the integrated circuit package, wherein the second die is at least partially disposed in the hole.

10. The method of claim 7, wherein the electromagnetic shield box comprises one or more signal traces and one or more ground traces, wherein the one or more signal traces carry one or more signals from one side of the hole in the substrate to an opposite side of the hole in the substrate.

11. The method of claim 10, wherein the electromagnetic shield box comprises a flexible substrate.

12. The method of claim 10, wherein the electromagnetic shield box comprises one or more vias, wherein the one or more vias couple the one or more signal traces to one or more of the plurality of pads.

13. The method of claim 7, wherein the electromagnetic shield box is rigid.

14. A circuit board comprising:
a substrate comprising a top surface and a bottom surface, wherein a hole is defined in the substrate, wherein the hole extends from the top surface to the bottom surface;
a plurality of pads on the top surface of the substrate; and
means for shielding one or more components mounted on the circuit board,
wherein the means for shielding is at least partially disposed in the hole,
wherein the means for shielding mates with one or more of the plurality of pads on the top surface of the substrate.

15. A system comprising the circuit board of claim 14, further comprising an integrated circuit package mounted on the top surface of the substrate, the integrated circuit package comprising:
a circuit board, the circuit board of the integrated circuit package comprising a top surface and a bottom surface;
a first die mounted on the top surface of the circuit board of the integrated circuit package; and
a second die mounted on the bottom surface of the circuit board of the integrated circuit package, wherein the second die is at least partially disposed in the hole.

16. The circuit board of claim 14, wherein the means for shielding comprises one or more signal traces and one or more ground traces, wherein the one or more signal traces carry one or more signals from one side of the hole in the substrate to an opposite side of the hole in the substrate.

17. The circuit board of claim 16, wherein the means for shielding comprises a flexible substrate.

18. The circuit board of claim 16, wherein the means for shielding comprises one or more vias, wherein the one or more vias couple the one or more signal traces to one or more of the plurality of pads.

19. The circuit board of claim 14, wherein the means for shielding is rigid.

20. The circuit board of claim 14, wherein the means for shielding does not extend below the bottom surface of the circuit board.
